(19) United States
(12) Patent Application Publication
(10) Pub. No.: US 2024/0039429 A1
(43) Pub. Date: Feb. 1, 2024

(54) VIBRATION ENERGY HARVESTER, POWER ACCUMULATOR AND POWER SUPPLIER

(71) Applicant: City University of Hong Kong Shenzhen Futian Research Institute, Shenzhen (CN)

(72) Inventors: Jian Lu, Shenzhen (CN); Fengqian Hao, Shenzhen (CN); Biao Wang, Shenzhen (CN); Zhengbao Yang, Shenzhen (CN)

(21) Appl. No.: 18/140,173

(22) Filed: Apr. 27, 2023

(30) Foreign Application Priority Data
Aug. 1, 2022 (CN) 202210917857.4

(51) Int. Cl. H02N 2/18; H02N 2/00

(52) U.S. Cl. CPC H02N 2/186; H02N 2/0055; H02J 7/32

(57) ABSTRACT

A vibration energy harvester, a power accumulator and a power supplier, including: a multi-stable shell with one or more bistable regions and at least one piezoelectric element fixed on a surface of the multi-stable shell. Each of the bistable regions has two different stable configurations, and different combinations of the stable configurations of the one or more bistable regions make the multi-stable shell have a plurality of different stable configurations. The one or more bistable regions are switched between the two stable configurations thereof when being excited by vibration energy, so that the multi-stable shell is switched between the plurality of stable configurations to deform the piezoelectric element to generate electric energy.

### CROSS-REFERENCE TO RELATED APPLICATION

This application claims priority to Chinese Patent Application No. 202210917857.4, filed on Aug. 1, 2022, which is hereby incorporated by reference in its entirety.

### TECHNICAL FIELD

The present disclosure relates to the technical field of renewable energy power generation, and particularly to a vibration energy harvester, a power accumulator and a power supplier.

### BACKGROUND

With the development of science and technology, the consumption of energy sources is increasing all over the world, while the reserves of traditional non-renewable resources such as oil and coal are gradually exhausted, which is far from ensuring the future needs of human lives. In addition, climate and environmental problems, such as greenhouse effect caused by the traditional energy sources, are increasingly restricting the survival and development of human beings. Therefore, the development of new renewable clean energy sources has gradually become an important development issue in various countries. Like the commonly used clean energy sources such as solar energy, wind energy and ocean energy, vibration energy is widely existed in the human environment, but is rarely collected and utilized. Compared with other clean energy sources, the vibration energy normally existing in mechanical structures is less affected by external factors such as weather and closely related to human productions and lives. Therefore, the collection and utilization of the vibration energy have attracted more and more attention.

As the vibration may cause structural deformation, the commonly used method for vibration energy harvesting is utilizing piezoelectric material to convert the deformation energy generated by vibration into electrical energy. A large number of studies show that this method is simple and effective. Therefore, a variety of linear and nonlinear vibration energy harvesters were invented.

The linear vibration energy harvester has a high energy conversion efficiency only at its fixed frequency. Therefore, its energy absorption effect will be greatly reduced once the vibration frequency changes. As a result, the linear vibration energy harvester is difficult to be popularized and used in practical application scenarios with variable vibration frequencies. However, the nonlinear vibration energy harvester has the advantages of wide working frequency range, large output energy and high conversion efficiency due to its nonlinear characteristics, so it is very suitable for practical application scenarios with variable vibration frequencies. The traditional magnetic bistable vibration energy harvester has the disadvantages of complex structure and high energy consumption. The bistable vibration energy harvester fabricated by composite laminate has the disadvantages of complex manufacturing, uncontrollable deformation and simplex mounting due to the limitation of the material itself.

It should be noted that the above description of the background art is only for the convenience of clearly and completely explaining the technical solutions of the present disclosure, and to facilitate the understanding by those skilled in the art. Such technical solutions should not be considered as well known to those skilled in the art merely because they are set forth in the background section of the present disclosure.

### SUMMARY

The present disclosure provides a vibration energy harvester, a power accumulator and a power supplier to solve at least part of the above problems pointed out in the background section.

It is a first aspect of the present disclosure to provide a vibration energy harvester, which includes a multi-stable shell with one or more bistable regions and at least one piezoelectric element bonded on the surface of the multi-stable shell. Each of the bistable regions has two different stable configurations switchable into each other. The switching process of the bistable region between the two stable configurations is a nonlinear motion. Different combinations of the stable configurations of the one or more bistable regions make the multi-stable shell have a plurality of different stable configurations. The one or more bistable regions are switched between the two stable configurations thereof when being excited by vibration energy, so that the multi-stable shell is switched between the plurality of stable configurations to deform the piezoelectric element to generate electric energy.

It is a second aspect of the present disclosure to provide an electric accumulator, including an electric accumulation element and the vibration energy harvester according to the embodiments of the first aspect. The electric accumulation element is electrically coupled to a piezoelectric element of the vibration energy harvester to store electric energy generated by the piezoelectric element.

It is a third aspect of the present disclosure to provide a power supplier, including a power transmission circuit and the vibration energy harvester according to the embodiments of the first aspect. The power transmission circuit is electrically coupled to a piezoelectric element of the vibration energy harvester to supply electric energy generated by the piezoelectric element to a load.

The embodiments of the present disclosure have the following advantageous effects.

1. Under the excitation of vibration energy, the multi-stable shell in the present disclosure can be subjected to a multi-stable transformation to cause a large deformation, which makes the piezoelectric material of the piezoelectric element produce a piezoelectric effect to generate electric energy. Compared with the prior art, the power generation is larger and the energy conversion efficiency is higher.

2. The multi-stable shell in the present disclosure represents nonlinear characteristics during the configuration transformation, so that the energy harvester has a broadband characteristic and achieves a good energy absorption effect in a certain frequency band, thus being applicable to practical scenarios with variable vibration frequencies.

3. The multi-stable shell of the present disclosure has a local bistable characteristic, which enables the energy harvester to have a greater design freedom and can be designed in different configurations according to different vibration needs, so it is easy in machining and controllable in deformation.

With reference to the following description and drawings, the specific embodiments of the present disclosure are disclosed in detail, and the ways in which the principles of the present disclosure can be adopted are pointed out. It should be appreciated that the embodiments of the present disclosure are not limited in scope. Within the scope of the spirit and clauses of the appended claims, the embodiments of the present disclosure include many changes, modifications and equivalents.

### BRIEF DESCRIPTION OF THE DRAWINGS

The drawings are included to provide a further understanding of the embodiments of the present disclosure, constitute a part of the specification, illustrate the embodiments of the present disclosure, and together with the description, explain the principles of the present disclosure. Obviously, the drawings in the following description only illustrate some embodiments of the present disclosure. Those of ordinary skill in the art can obtain other drawings from these drawings without any inventive efforts. In the drawings:

FIG. 1 is a schematic diagram of a configuration transformation of a vibration energy harvester according to an embodiment of the present disclosure;

FIG. 2 is a schematic diagram of a bistable region holding an downward convex configuration according to an embodiment of the present disclosure;

FIG. 3 is a schematic diagram of a bistable region holding a upward convex configuration according to an embodiment of the present disclosure;

FIGS. 4a to 4f are schematic diagrams of bistable regions of various shapes according to an embodiment of the present disclosure;

FIGS. 5a to 5d are schematic diagrams of multi-stable shells of various shapes according to an embodiment of the present disclosure;

FIGS. 6a and 6b are schematic diagrams of a multi-stable shell connected to a vibration source according to an embodiment of the present disclosure;

FIGS. 7a and 7b are schematic diagrams of a multi-stable shell connected to a vibration source according to another embodiment of the present disclosure;

FIG. 8 is a schematic diagram of a plurality of piezoelectric elements provided on a multi-stable shell according to an embodiment of the present disclosure;

FIG. 9 is a schematic diagram of relationships between the output voltage and scanning frequency obtained by performing frequency sweep tests on a vibration energy harvester according to an embodiment of the present disclosure and a linear vibration energy harvester of the prior art, respectively;

FIG. 10 is a schematic diagram of a power accumulator according to an embodiment of the present disclosure;

FIG. 11 is a schematic diagram of a power supplier according to an embodiment of the present disclosure.

### DETAILED DESCRIPTION

The foregoing and other features of the present disclosure will become apparent from the following description with reference to the drawings. In the description and drawings, specific embodiments of the present disclosure are specifically disclosed, which are some embodiments in which the principles of the present disclosure can be applied. It should be appreciated that the present disclosure is not limited to the described embodiments, but on the contrary, the present disclosure includes any modification, variation and equivalent that falls within the scope of the appended claims. In the embodiments of the present disclosure, unless otherwise stated, the terms ‘a plurality of’ and ‘multiple’ both means two or more, and the term ‘multi-stable’ means two or more stable states.

The implementations of the embodiments of the present disclosure will be described below with reference to the drawings.

Embodiments of a first aspect of the present disclosure provide a vibration energy harvester.

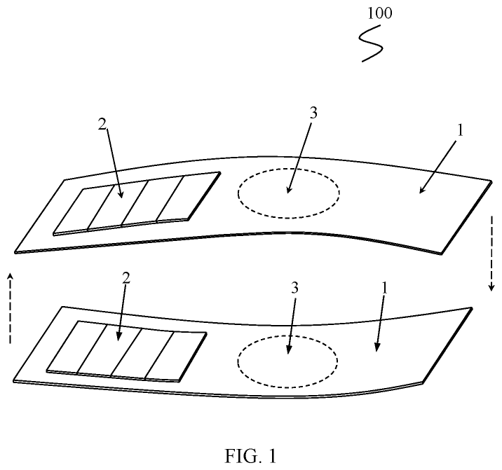

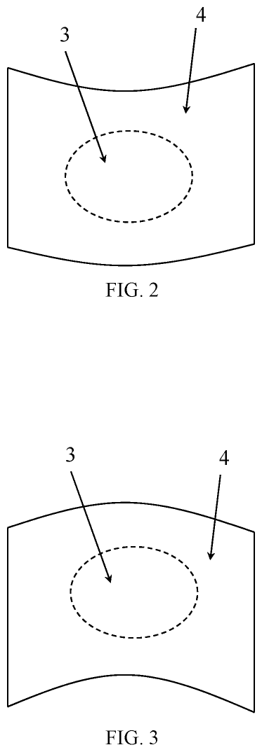

FIG. 1 is a schematic diagram of a configuration transformation of a vibration energy harvester according to an embodiment of the present disclosure, FIG. 2 is a schematic diagram of a bistable region holding a downward convex configuration according to an embodiment of the present disclosure, and FIG. 3 is a schematic diagram of a bistable region holding an upward convex configuration according to an embodiment of the present disclosure.

As illustrated in FIG. 1, a vibration energy harvester 100 includes a multi-stable shell 1 and at least one piezoelectric element 2.

The multi-stable shell 1 has one or more bistable regions 3. In the embodiment illustrated in FIG. 1, the multi-stable shell 1 has one bistable region 3. In other embodiments, the multi-stable shell 1 may have a plurality of bistable regions 3 distributed at intervals. Each of the bistable regions 3 has two different stable configurations that can be switched into each other. In other words, each of the bistable regions 3 is capable of selectively holding two different stable configurations without any external input energy or support. The switching motion of the bistable region 3 between the two stable configurations is nonlinear. For example, the two stable configurations of the bistable region 3 are a downward convex configuration (FIG. 2) and an upward convex configuration (FIG. 3), respectively. The bistable region 3 is capable of holding the downward convex configuration or the upward convex configuration without any maintenance energy, and the switching motion of the bistable region 3 between the downward convex configuration and the upward convex configuration is nonlinear.

Different combinations of the stable configurations of one or more bistable regions 3 make the multi-stable shell 1 have different stable configurations. When the multi-stable shell 1 includes n bistable regions 3, theoretically there exist 2ⁿ stable configurations for the multi-stable shell 1, so that the multi-stable shell 1 has multi-stable characteristics.

The configuration switching of the bistable region 3 changes the configuration of the bistable shell 1. Referring to FIG. 1, the bistable shell 1 includes one bistable region 3. When the bistable region 3 holds the upward convex configuration, the bistable shell 1 wholly is in an upward convex configuration. When the bistable region 3 is switched from the upward convex configuration to the downward convex configuration, the bistable shell 1 also changes to a downward convex configuration. When the multi-stable shell 1 includes a plurality of bistable regions 3, the configuration switching of any one or more of the bistable regions 3 will lead to the configuration change of the multi-stable shell 1.

The piezoelectric element 2 is fixed on a surface of the multi-stable shell 1. For example, one surface of the multi-stable shell 1 is provided with the piezoelectric element 2, or two opposite surfaces of the multi-stable shell 1 are provided with the piezoelectric elements 2, respectively. The number of the piezoelectric element 2 on each surface of the multi-stable shell 1 may be one or more.

When the vibration energy to be collected is continuously applied to the multi-stable shell 1, the configuration of the bistable region 3 is continuously switched between the two stable configurations thereof as excited by the vibration energy continuously. The continuous switching of the configurations of one or more bistable regions 3 makes the multi-stable shell 1 continuously switch between its multiple stable configurations, so that the piezoelectric element 2 is continuously deformed (as illustrated in FIG. 1) to continuously generate electric energy, thus converting the vibration energy into electric energy and realizing the collection of the vibration energy.

It should be noted that vibration energy may be generated non-artificially such as by a vibration source, and may also be generated by an artificially applied external force. The vibration energy may be directly applied to the bistable region 3. Alternatively, the vibration energy may be applied to any other region (called as a non-bistable region) of the multi-stable board 1 except the bistable region 3, so as to be transferred from the non-bistable region to the bistable region 3. Alternatively, the vibration energy may be applied to both the bistable region 3 and the non-bistable region.

In this embodiment of the present disclosure, the multi-stable shell 1 is provided, and subjected to a multi-stable transformation under the excitation of the vibration energy. The multi-stable transformation causes a large deformation, so that the piezoelectric material of the piezoelectric element 2 causes a strong piezoelectric effect to generate more electric energy, thus generating more electricity and achieving higher energy conversion efficiency compared with the prior art. The electric energy generated by the piezoelectric element 2 may be directly stored in a storage battery, or may be directly transmitted to small electric devices such as sensors after being processed.

As the multi-stable shell 1 has the local bistable characteristic, the harvester has a greater design freedom and may be designed in different configurations according to different vibration needs, while being easy in machining and controllable in deformation.

The process of switching between the two stable states for the bistable region 3 is destabilising from one stable state and snapping into the other stable state, and the switching motion of the bistable region 3 between the two stable states is a nonlinear motion. In other words, the configuration switching of the bistable region 3 is nonlinear, so that the multi-stable transformation of the multi-stable shell 1 is also nonlinear (called as a nonlinear multi-stable transformation). Therefore, the energy harvester of the present disclosure is a nonlinear energy harvester. Compared with the linear energy harvester which only has a good energy absorption effect at its own natural frequency, the energy harvester of the present disclosure achieves a good energy absorption effect in a certain frequency band, and has a broadband characteristic, thus being applicable to practical scenarios with variable vibration frequencies.

In order to verify the broadband characteristic of the energy harvester of the present disclosure, and to compare the energy conversion efficiency of the energy harvester of the present disclosure with that of the linear energy harvester of the prior art, frequency sweep tests are carried out on the two types of energy harvesters, respectively. FIG. 9 illustrates a schematic diagram of relationships between the output voltage and scanning frequency, which are obtained by performing frequency sweep tests on a vibration energy harvester of the present disclosure and a linear vibration energy harvester of the prior art, respectively. The graph in the block 11 of FIG. 9 illustrates a relationship between the output voltage and the scanning frequency of the linear vibration energy harvester, and the graph in the block 12 of FIG. 9 illustrates the relationship between the output voltage and the scanning frequency of the vibration energy harvester of the present disclosure.

As illustrated in FIG. 9, in the frequency sweep test of the linear energy harvester, the output voltage signal only has a peak value (i.e., a maximum output voltage) at a natural frequency 13 and presents a symmetrical characteristic. But in the frequency sweep test of the vibration energy harvester of the present disclosure, the output voltage signal presents a plurality of peaks in a frequency band 14 where the natural frequency 13 is located. At this time, the piezoelectric signal increases obviously, indicating that the high voltage signal continuously appears in the specific frequency band 14, which proves that the energy harvester of the present disclosure achieves a significant energy absorption effect throughout the frequency band 14, has a broadband characteristic, and has better energy absorption effect than that of the linear energy harvester.

The plurality of output voltage signal peaks occurring in the frequency band 14 (see the circle 15 in FIG. 9) correspond to the continuous multi-stable transformation of the multi-stable shell 1 in the frequency band 14, which indicates that the nonlinear multi-stable transformation of the multi-stable shell 1 in the present disclosure can significantly improve the energy absorption effect. The obvious feature of an effective working frequency band of the energy harvester is that the output voltage signal increases significantly, so the frequency band 14 corresponding to the nonlinear multi-stable transformation of the multi-stable shell 1 is the effective working frequency band of the energy harvester.

Through the research, the inventor finds that the effective working frequency band of the vibration energy harvester of the present disclosure is positively correlated to the vibration intensity (e.g., the acceleration) of the vibration source, and the bandwidth of the effective working frequency band increases along with the vibration intensity. In the design of the vibration energy harvester, the working frequency band of the vibration energy harvester may be designed according to the vibration frequency of the vibration source, so as to make the effective working frequency band of the vibration energy harvester cover the vibration frequency of the vibration source. For example, during implementation, the working frequency band of the vibration energy harvester is designed by controlling the size and shape of the bistable shell 1, the parameters of the piezoelectric material of the piezoelectric element 2, the position of the piezoelectric element 2 on the bistable shell 1, and the residual stress introduced into the bistable region 3, so as to make the effective working frequency band cover the vibration frequency of the vibration source. For the manufactured vibration energy harvester, the later adjustment of the effective working frequency band may be achieved by adjusting the residual stress of the bistable region 3 and the position or the parameters of the piezoelectric element 2. Therefore, the vibration energy harvester of the present disclosure further has the advantage that its effective working frequency band is adjustable, so that a suitable working frequency band of the vibration energy harvester can be customized according to the vibration sources with different vibration intensities and vibration frequencies.

In some embodiments, the frequency of the vibration energy to be collected may change within a certain frequency range, which is the effective working frequency range of the vibration energy harvester. Specifically, the effective working frequency range is a range that widens from the natural frequency of the multi-stable shell to both sides, and the specific extending range is positively correlated to the intensity of the vibration source. Generally, the effective working frequency range of the vibration energy harvester is a low frequency range of 1 Hz to 200 Hz.

In some embodiments, the nonlinear switching motion of the bistable region 3 between the two different stable states is snap-through. For example, under the excitation of the vibration energy, the bistable region 3 can be switched between the downward convex configuration (FIG. 2) and the upward convex configuration (FIG. 3) by snap-through.

In some embodiments, the multi-stable shell 1 is obtained by treating a local region of a metal shell with the surface mechanical attrition treatment (SMAT) technology. The treated local region becomes the bistable region 3 having a nanocrystalline surface layer with a gradient structure, so that the bistable region 3 has the mechanical properties as excellent as the gradient nanostructure material. Based on the treatment method, the multi-stable shell 1 has a simple manufacturing process, and can be obtained by machining a metal shell with an arbitrary shape.

Optionally, the metal shell is made of aluminum alloy, stainless steel, titanium alloy, nickel-based alloy, magnesium alloy or other metal materials.

Optionally, the metal shell is a flat or curved shell with uniform or uneven thickness.

Optionally, metal shell has a thickness of 0.1 mm to 2 mm.

In this embodiment, the surface mechanical attrition treatment technology may be adopted to treat the front and back sides of the local region of the metal shell. The grains of surface layer material of the treated local region (also called as a treated region) are refined to nanometer level. The grain size decreases as being closer to the surface layer presenting a typical characteristic of gradient nanostructure, which improves the strength, corrosion resistance and fatigue resistance of the bistable region 3. While the grain is refined, the residual stress is also introduced into the material of the treated region. The material of the treated region is plastically deformed under the action of the surface mechanical attrition treatment technology, and the deformation will be restrained or restricted by the surrounding untreated region 4 (also called as the non-bistable region, see FIGS. 2 and 3), and then represent an upward convex configuration and a downward convex configuration along a normal direction. Since there are residual stresses in the surface materials on both sides of the treated region, the above two configurations are independent and stable under the maintenance of residual stresses, without being maintained with an external force, and can be switched under the vibration with a certain intensity.

For example, FIG. 2 illustrates that the initial configuration of the bistable region 3 is a downward convex configuration, and when the vibration condition meets the configuration switching requirement, the bistable region 3 is switched to the upward convex configuration as shown in FIG. 3. The continuous vibration causes the continuous switching between the upward convex configuration and downward convex configuration, and the energy required for switching may be controlled by adjusting the amount of residual stress introduced during machining, so as to adapt to different vibration conditions. In FIGS. 2 and 3, the downward convex configuration and the upward convex configuration of the bistable region 3 are that the bistable region 3 gradually bulges downward or upward from the outer edge to the center, respectively, and the bistable region 3 has a non-uniform curvature.

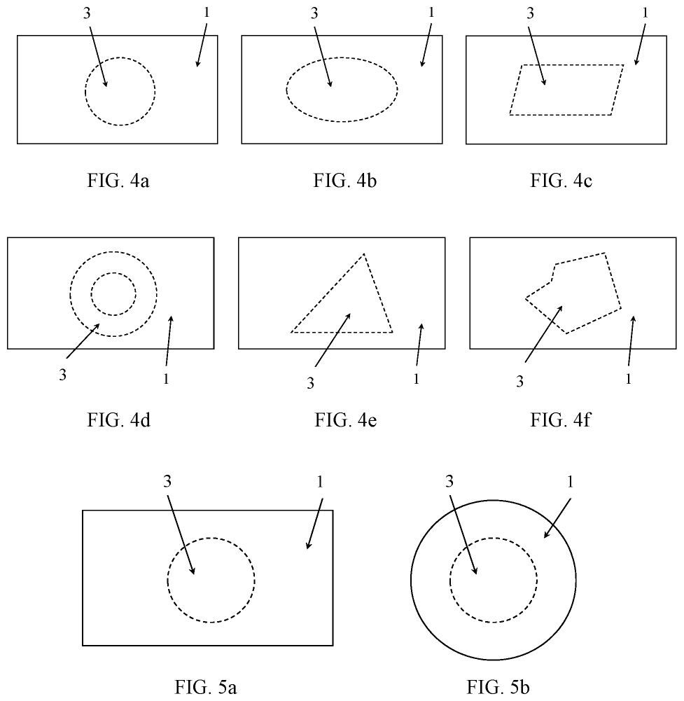

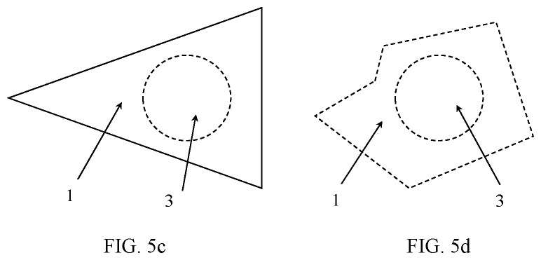

The shape of the bistable region 3 may be circular (as illustrated in FIG. 4a), elliptical (as illustrated in FIG. 4b), quadrilateral (as illustrated in FIG. 4c), annular (as illustrated in FIG. 4d), triangular (as illustrated in FIG. 4e) or any other closed pattern (as illustrated in FIG. 4f). During machining of the bistable region 3, in order to obtain the required shape, the non-treated region of the metal shell may be covered by a mold, and the uncovered region is treated using the surface mechanical attrition treatment technology to obtain the bistable region 3 with the required shape. The number and positions of the bistable regions 3 on the metal shell may be designed according to actual needs. In addition, the shape of the multi-stable shell 1 may also be designed as quadrilateral (as illustrated in FIG. 5a), circular (as illustrated in FIG. 5b), a triangular (as illustrated in FIG. 5c) or any other shape (as illustrated in FIG. 5d) according to actual needs.

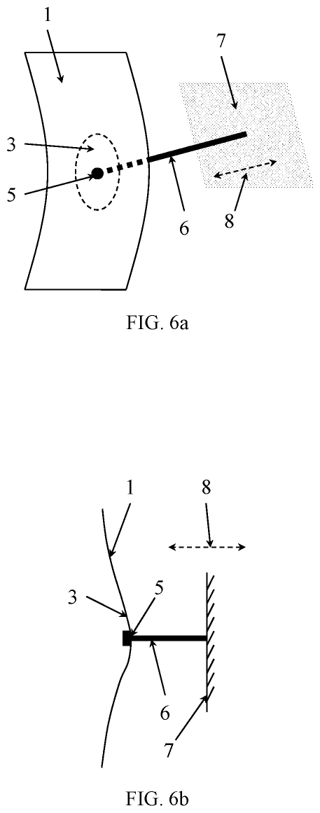

In some embodiments, as illustrated in FIGS. 6a and 6b, the harvester further includes a connecting rod 6, one end of which is connected to the bistable region 3, and the other end of which is connected to the vibration source 7. The bistable region 3 is connected to the vibration source 7 through the connecting rod 6 in a manner approximately perpendicular to the vibration direction 8 of the vibration source 7, so that the vibration energy generated by the vibration source 7 can be effectively transmitted to the multi-stable shell 1, and the mounting is simple and convenient. For example, the connecting rod 6 is approximately perpendicular to the bistable region 3 and parallel to the vibration direction 8 of the vibration source 7.

In order to conveniently connect the bistable region 3 and the connecting rod 6, a through hole 5 may be punched at any position in the bistable region 3, and the connecting rod 6 passes through the through hole 5. The through hole 5 provided at the circle center of the bistable region 3 will facilitate the transmission of the vibration energy. When the shape of the multi-stable shell 1 is centrosymmetric, such as a square or a circle, and the shape of the bistable region 3 is circular, the connection mode of this embodiment is particularly suitable for connecting the bistable region 3 and the vibration source 7.

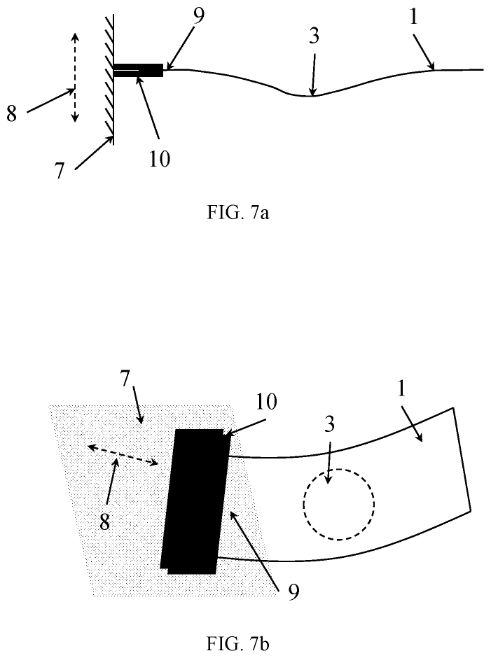

In other embodiments, as illustrated in FIGS. 7a and 7b, the harvester further includes a clamp 10 with two clamping ends, one of which is connected to an end 9 of the bistable shell 1, and the other of which is connected to the vibration source 7. The bistable shell 1 is connected to the vibration source 7 through the clamp 10 in a manner approximately perpendicular to the vibration direction 8 of the vibration source 7, so that the vibration energy generated by the vibration source 7 can be effectively transmitted to the bistable shell 1, and the mounting is simple and convenient. When the multi-stable shell 1 is rectangular or any other strip-shape, one clamping end of the clamp 10 is connected to one of the two ends of the multi-stable shell 1 in the length direction.

In some embodiments, the vibration energy harvester further includes a vibration source 7 with a variable vibration frequency. In order to obtain as much vibration energy as possible, the vibration source 7 is directly connected to the multi-stable shell 1.

In some embodiments, a single piezoelectric element 2 may be a single piezoelectric piece. Alternatively, a single piezoelectric element 2 may be formed by a plurality of piezoelectric pieces connected in series or in parallel (as illustrated in FIG. 1).

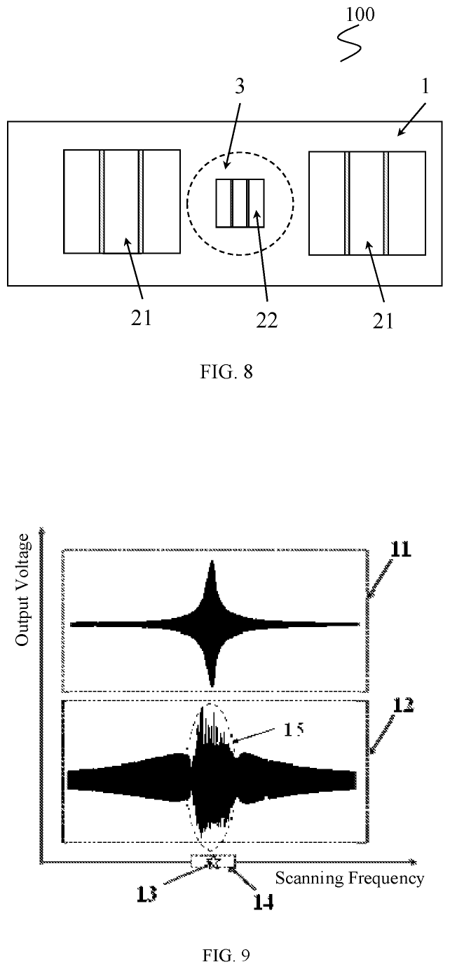

In some embodiments, as illustrated in FIG. 8, a surface of at least one bistable region 3 is provided with a piezoelectric element 22; and/or, a surface of other region (i.e., the untreated region 4 in FIGS. 2 and 3) of the multi-stable shell 1 excluding the bistable region 3 is provided with a piezoelectric element 21.

Since the bistable region 3 has a large deformation during the configuration switching of the multi-stable shell 1 and the untreated region 4 has a small deformation during the configuration switching of the multi-stable shell 1, the piezoelectric elements 22 on the surface of the bistable region 3 may be made of a piezoelectric material with a large deformation capacity, such as PVDF, while the piezoelectric element 21 on the surface of the untreated region 4 may be made of a piezoelectric material with a small deformation capacity, such as piezoelectric ceramics or piezoelectric crystals. Certainly, the piezoelectric element 21 on the surface of the untreated region 4 may also be made of a piezoelectric material with a large deformation capacity. Therefore, the present disclosure allows the use of piezoelectric elements with different deformation capabilities.

In some embodiments, the surface of the piezoelectric element 2 is attached and fixed to the surface of the multi-stable shell 1. The piezoelectric element 2 may be fixed to the surface of the multi-stable shell 1 by adhesive, and the specific adhesive method may be local adhesive or integral adhesive. However, the present disclosure is not limited thereto, and the piezoelectric element 2 may be connected to the multi-stable shell 1 in other ways, such as a detachable connection.

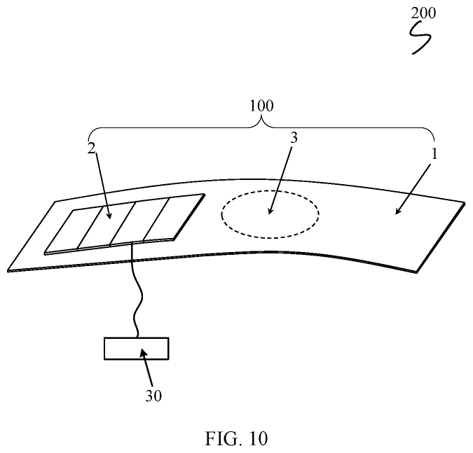

As illustrated in FIG. 10, embodiments of a second aspect of the present disclosure provide an electric accumulator 200, which includes an electric accumulation element 30 and the vibration energy harvester 100 according to the embodiments of the first aspect of the present disclosure. The electric accumulation element 30 is electrically coupled to the piezoelectric element 2 of the vibration energy harvester 100. The electric energy generated by the piezoelectric element 2 may be directly stored in the electric accumulation element 30. For example, the electric accumulation element 30 is a storage battery.

Since the structure and the effect of the vibration energy harvester 100 have been described in detail in the embodiment of the first aspect, relevant contents are incorporated here, and the description is omitted.

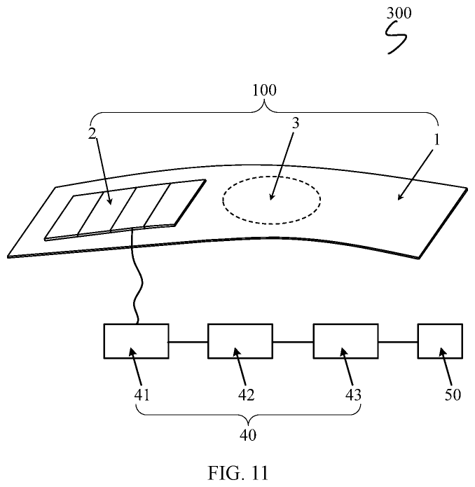

As illustrated in FIG. 11, embodiments of a third aspect of the present disclosure provides a power supplier 300, which includes the vibration energy harvester 100 according to the embodiments of the first aspect of the present disclosure and a power transmission circuit 40. The power transmission circuit 40 is electrically coupled to the piezoelectric element 2 of the vibration energy harvester 100, and is configured to supply electric energy generated by the piezoelectric element 2 to a load 50, so as to directly supply power to the load 50. For example, the load 50 is a small electronic device such as a sensor.

Since the structure and the effect of the vibration energy harvester 100 have been described in detail in the embodiment of the first aspect, relevant contents are incorporated here, and the description is omitted.

In some embodiments, the power transmission circuit 40 includes a rectifier 41, a super capacitor 42 and a voltage regulating device 43 which are electrically coupled in sequence. The rectifier 41 is electrically coupled to the piezoelectric element 2 of the vibration energy harvester 100. The electric energy generated by the piezoelectric element 2 is converted into direct current by the rectifier 41, then stored in the super capacitor 42, and then regulated by the voltage regulating device 43 and supplied to the load 50.

The exemplary embodiments of the present disclosure are described above with reference to the drawings. Many features and advantages of these embodiments will be clear from the detailed description, so the appended claims are intended to cover all the features and advantages of these embodiments that fall within their true spirit and scope. In addition, since many modifications and changes are easily conceivable for those skilled in the art, it is not intended to limit the embodiments of the present disclosure to the precise structures or operations illustrated and described, but to cover all suitable modifications and equivalents falling within the scope.

1. A vibration energy harvester, comprising:
a multi-stable shell with one or more bistable regions, each of which has two different stable configurations switchable into each other, wherein a switching motion of the bistable region between the two stable configurations is a nonlinear motion, and different combinations of the stable configurations of the one or more bistable regions make the multi-stable shell have a plurality of different stable configurations;
at least one piezoelectric element fixed on a surface of the multi-stable shell;
wherein the one or more bistable regions are switched between the two stable configurations thereof when being excited by vibration energy, so that the multi-stable shell is switched between the plurality of stable configurations to deform the piezoelectric element to generate electric energy.

2. The vibration energy harvester according to claim 1, wherein the nonlinear motion is snap-through.

3. The vibration energy harvester according to claim 1, wherein the two stable configurations of the bistable region are an upward convex configuration and a downward convex configuration.

4. The vibration energy harvester according to claim 1, wherein the vibration energy is provided by a vibration source, and the multi-stable shell is connected to the vibration source in a manner substantially perpendicular to a vibration direction of the vibration source.

5. The vibration energy harvester according to claim 4, further comprising:
a clamp connected to one end of the multi-stable shell, wherein the multi-stable shell is connected to the vibration source through the clamp in a manner substantially perpendicular to the vibration direction of the vibration source.

6. The vibration energy harvester according to claim 4, further comprising:
a connecting rod, one end of which is connected to the bistable region, wherein the bistable region is connected to the vibration source through the connecting rod in a manner substantially perpendicular to the vibration direction of the vibration source.

7. The vibration energy harvester according to claim 1, wherein the vibration energy is originated from the vibration source with variable vibration frequencies.

8. The vibration energy harvester according to claim 1, wherein,
the piezoelectric element is provided on a surface of at least one bistable region; and/or,
the piezoelectric element is provided on a surface of a non-bistable region of the multi-stable shell excluding the bistable region.

9. The vibration energy harvester according to claim 1, wherein,
the piezoelectric element is a single piezoelectric piece; or,
the piezoelectric element is formed by a plurality of piezoelectric pieces connected in series or in parallel.

10. The vibration energy harvester according to claim 1, wherein the multi-stable shell is obtained by processing a local region of a metal shell with a surface mechanical attrition treatment, and the treated local region is the bistable region having a nanocrystalline surface layer.

11. The vibration energy harvester according to claim 10, wherein the metal shell is a flat or curved shell with uniform or uneven thickness.

12. The vibration energy harvester according to claim 10, wherein the metal shell has a thickness of 0.1 mm to 2 mm.

13. An electric accumulator, comprising an electric accumulation element and the vibration energy harvester according to claim 1, wherein the electric accumulation element is electrically coupled to the piezoelectric element of the vibration energy harvester to store electric energy generated by the piezoelectric element.

14. A power supplier, comprising a power transmission circuit and the vibration energy harvester according to claim 1, wherein the power transmission circuit is electrically coupled to the piezoelectric element of the vibration energy harvester to supply electric energy generated by the piezoelectric element to a load.
